(19) United States
(12) Patent Application Publication
(10) Pub. No.: US 2013/0146124 A1
(43) Pub. Date: Jun. 13, 2013

(54) LARGE-SCALE INTEGRATED RADIANT ENERGY COLLECTOR

(71) Applicant: Smart Solar International, Inc., Santa Clara, CA (US)

(72) Inventors: Gary McClure, San Jose, CA (US); Joseph Lichy, San Jose, CA (US)

(73) Assignee: Smart Solar International, Inc., Santa Clara, CA (US)

(21) Appl. No.: 13/684,058

(22) Filed: Nov. 21, 2012

Related U.S. Application Data
(60) Provisional application No. 61/563,344, filed on Nov. 23, 2011.

(51) Int. Cl. H01L 31/052; H01L 31/058; F24J 2/10

(52) U.S. Cl. CPC H01L 31/0525; F24J 2/10; H01L 31/058
USPC 136/248; 136/246; 126/684

(57) ABSTRACT

A large-scale integrated radiant energy collector includes a receiver assembly including a plurality of receiver units, a plurality of flat mirror assemblies, and a tower configured to support the receiver assembly above the plurality of flat mirror assemblies. Each receiver unit includes an absorber and a reflector configured to concentrate received radiant energy onto the absorber. Each of the plurality of flat mirror assemblies is configured to receive radiant energy and direct the radiant energy toward the receiver assembly. The receiver assembly may be configured to track the position of the radiant energy source (reflected by the flat mirror assemblies) in a first direction, and the plurality of flat mirror assemblies may be configured to track the position of the radiant energy source in a second direction.

### CLAIM OF PRIORITY

This application claims priority to Provisional Patent Application No. 61/563,344, filed on Nov. 23, 2011, which is hereby incorporated by reference.

### BACKGROUND OF THE INVENTION

The present invention relates to a system for collecting and concentrating radiant energy. For example, for collecting and concentrating radiant energy from the sun for use with high concentration photovoltaic (HCPV) technology.

Traditionally large concentration of solar energy using HCPV technology is achieved with a complicated and expensive two axis tracking system and large complicated minor assemblies.

### BRIEF DESCRIPTION OF THE INVENTION

The embodiments of the present invention provide a unique design of the large-scale integrated solar system, combining simple independent one-axis tracking elements: (1) an array of receivers located on a tower which track to the reflected light from a flat mirror array; and (2) a plurality of flat mirror focusing elements which track and reflect the sun to the receivers. Compared with traditional large-scale concentration systems, the large-scale integrated solar system in accordance with the embodiments of the present invention provides less complicated and less expensive solution to achieve high concentration of sunlight on a solar receiver.

In one embodiment of the invention, a large-scale integrated solar system includes a receiver assembly including a plurality of receiver units, a plurality of flat mirror assemblies, and a tower configured to support the receiver assembly above the plurality of flat mirror assemblies. Each receiver unit includes a photovoltaic converter configured to convert incident light into electricity, and a reflector configured to concentrate received light onto the photovoltaic converter. In an alternative embodiment of the invention each receiver unit includes a solar thermal absorber for converting sunlight into heat. In yet another alternative embodiment of the invention the receiver unit includes a hybrid absorber that converts a portion of the solar energy to electricity through photovoltaic or other means and a thermal absorber that converts a portion of the solar energy into heat. Each of the plurality of flat mirror assemblies is configured to receive sunlight and direct the sunlight toward the receiver assembly. Each of the plurality of flat mirror assemblies may direct the sunlight to one or more receiver units.

The plurality of flat mirror assemblies may be provided on the ground on one side or both sides of the tower, and may be arranged in rows. The receiver assembly may be configured to track the sun (reflected by the flat mirror assemblies) in a first direction, and the plurality of flat mirror assemblies may be configured to track the sun in a second direction. The first direction may be a north-south direction and the second direction may be an east-west direction. Alternatively the first and second directions can be any directions so long as the first direction is orthogonal to the second direction.

Each of the receiver units may be configured to rotate around a first axis perpendicular to the first direction, and each of the flat mirror assemblies may be configured to rotate around a second axis perpendicular to the second direction.

The receiver assembly may include a first array of receiver units provided on a first side of the tower and arranged in the first direction, and a second array of receiver units provided on a second side of the tower opposite to the first side and arranged in the first direction. The first axis for each of the receiver units in the first array may be tilted by a first angle with respect to a vertical direction. The first axis for each of the receiver units in the second array may be tilted by a second angle with respect to the vertical direction.

The first angle may be determined based on a height of the tower and a distance between the tower and a farthest one of the plurality of flat mirror assemblies provided on the first side of the tower. The second angle may be determined based on the height of the tower and a distance between the tower and a farthest one of the plurality of flat mirror assemblies provided on the second side of the tower.

In one aspect of the invention, the large-scale integrated solar system may further include a first motor for rotating each of the receiver units around the first axis (perpendicular to the first direction), and a second motor for rotating each of the flat mirror assemblies around the second axis (perpendicular to the second direction). The first motor and the second motor may be independently controlled in a synchronized manner so as to provide a dual-axis control for tracking the sun. The second motor may rotate the plurality of flat mirror assemblies row by row with respect to the receiver assembly.

The tower may include a receiver mount portion and at least one pole. The tower may accommodate a cable for transmitting the electricity generated by the receiver assembly.

While the embodiments of the invention presented here are intended for use as collectors of solar energy, other applications of the current invention are envisioned. For example, the invention could be used to concentrate radiant energy from other astronomical bodies such as stars, planets, or satellites. This would be useful in the fields of astronomy and communications.

### BRIEF DESCRIPTION OF THE DRAWINGS

The present invention is illustrated by way of example, and not by way of limitation, in the FIGS. of the accompanying drawings and in which like reference numerals refer to similar elements and in which:

FIG. 1 is a schematic diagram illustrating an overall design of the large-scale integrated solar system in accordance with one embodiment of the present invention.

FIG. 2A is a schematic side view of an example of the large-scale integrated solar system viewed from the south in accordance with an embodiment of the present invention.

FIG. 2B is a schematic top view of the example of the large-scale integrated solar system viewed from above in accordance with an embodiment of the present invention.

FIG. 2C is a schematic side view of the example of the receiver tower of the large-scale integrated solar system viewed from the west in accordance with an embodiment of the present invention.

FIG. 3 is a schematic diagram illustrating an overall design of the large-scale integrated solar system in accordance with another embodiment of the present invention.

FIG. 4 is a diagram illustrating an example of a structure of the receiver assembly in accordance with one embodiment of the present invention.

FIG. 5 is a diagram illustrating a structure of the tower having a receiver support truss frame and a plurality of support posts in accordance with one embodiment of the present invention.

FIG. 6 is a diagram illustrating more details of the receiver support truss frame and the support post.

FIG. 7 is a diagram illustrating a structure of a flat mirror assembly (Heliostat) in accordance with one embodiment of the present invention.

FIGS. 8A and 8B are diagrams schematically illustrating an example of a large-scale integrated system in accordance with one embodiment of the present invention.

### DETAILED DESCRIPTION OF EMBODIMENTS OF THE INVENTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

The large-scale integrated radiant energy collector in accordance with one embodiment of the present invention may be used for a method and system for generating electrical power by photovoltaic converters in a large utility scale so as to provide electrical power for consumer use (large-scale integrated solar system). The large-scale integrated solar system in accordance with one embodiment of the present invention may also be applied to a method and system for generating electrical power for use by an electric train system, for example, by providing the large-scale integrated solar system adjacent to rails.

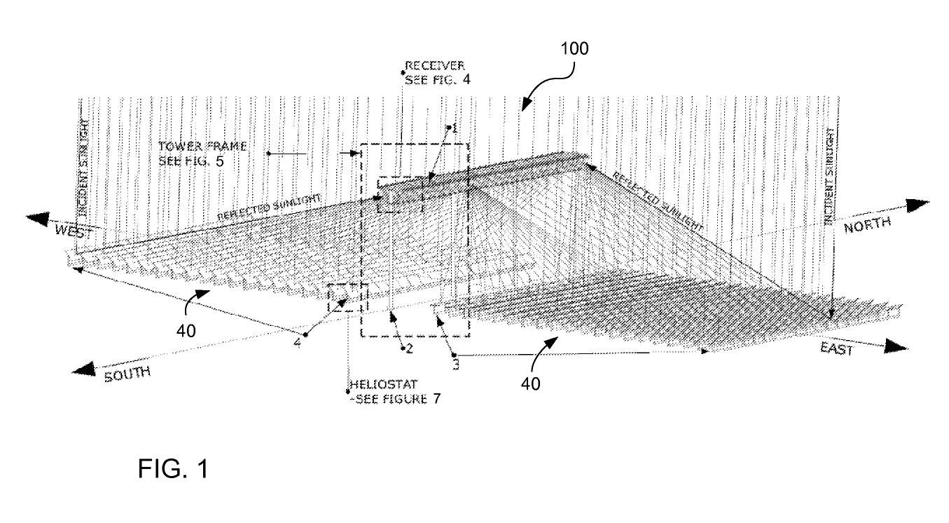

FIG. 1 schematically illustrates a perspective view of the large-scale integrated solar system 100 in accordance with one embodiment of the present invention.

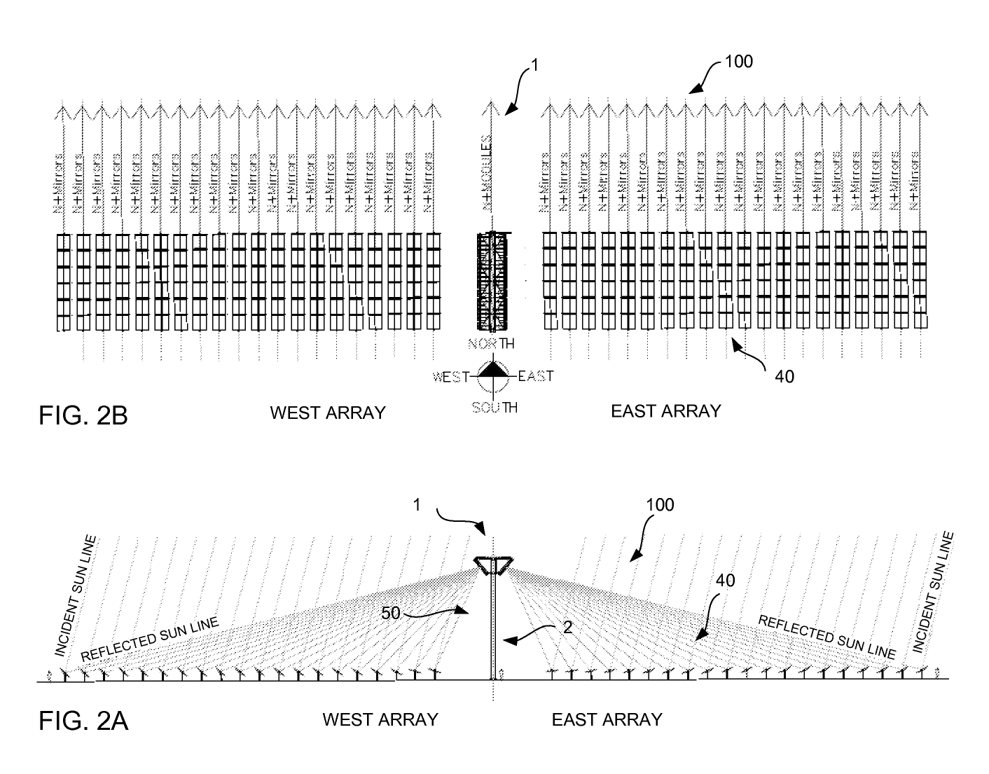

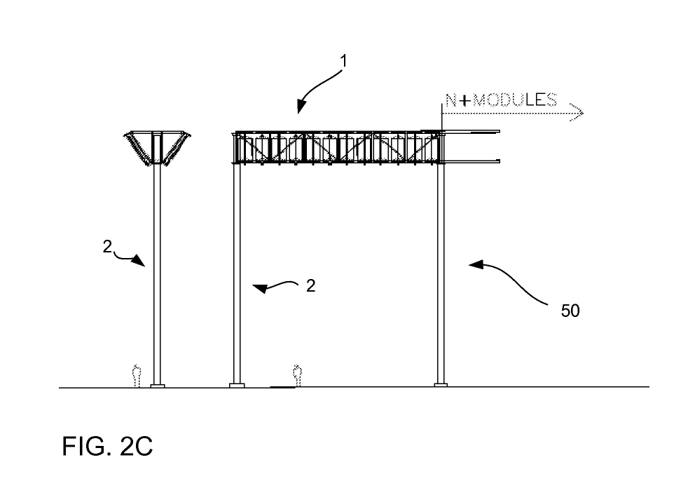

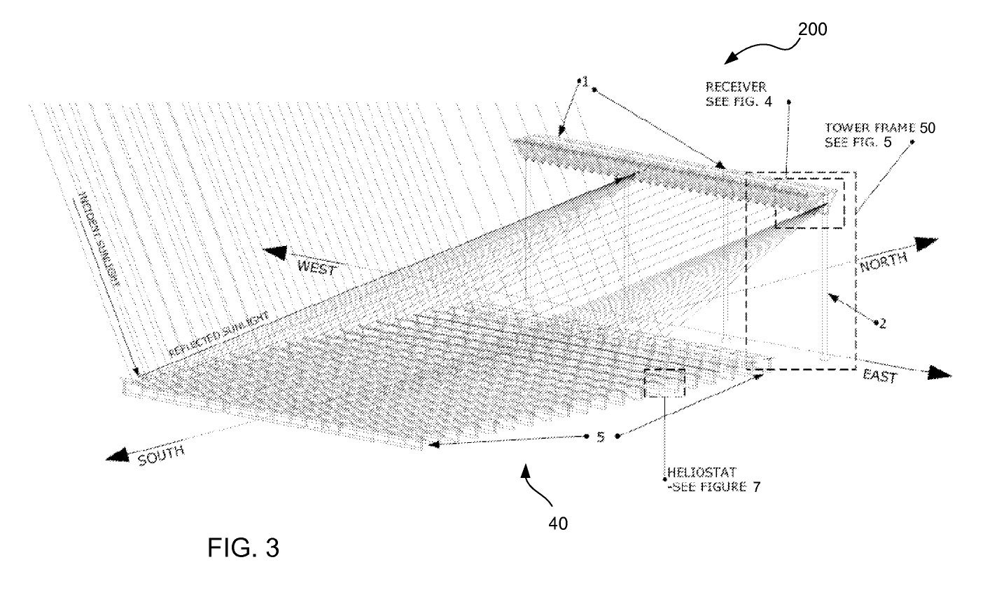

FIG. 2A illustrates a schematic side view of the large-scale integrated solar system 100 viewed from the south. FIG. 2B illustrates a schematic top view of the large-scale integrated solar system 100 viewed from above. FIG. 2C is a schematic side view of the receiver tower large-scale integrated solar system 100 viewed from the west.

As shown in FIGS. 1 through 2C, the large-scale integrated solar system 100 includes a receiver assembly 1, a plurality of flat mirror assemblies 40, and a tower 50. The receiver assembly 1 is also referred to as a receiver array & frame assembly. The receiver assembly 1 includes a plurality of receiver units (a receiver array) and a frame for holding the receiver array. The plurality of flat mirror assemblies 40 receive sunlight and direct the sunlight toward the receiver assembly 1. The tower 50 supports the receiver assembly 1 above the plurality of flat mirror assemblies 40. The tower 50 includes at least one support post 2.

Each receiver unit includes a radiant energy absorber, and a focusing optic configured to concentrate received light onto the energy absorber. For example, the radiant energy absorber may be a photovoltaic device for converting light energy into electrical energy, and the focusing optic may be a reflector configured to focus light on the photovoltaic device.

Thus, each receiver may include a photovoltaic converter configured to convert incident light into electricity, and a reflector configured to concentrate received light onto the photovoltaic converter. The reflector may be a parabolic mirror.

In accordance with another embodiment, the radiant energy absorber may be a thermal absorber for converting light energy into heat. In accordance with yet another embodiment, the radiant energy absorber may be a hybrid photovoltaic and thermal absorber for converting a portion of light energy into electricity, and a portion into heat.

In accordance with one embodiment of the present invention, the focusing optic in the receiver may be a refractive lens. In accordance with another embodiment, the focusing optic in the receiver may be a linear Fresnel lens, or a Fresnel lens.

The receiver assembly 1 receives focused light from the plurality of flat mirror assemblies 40. The flat mirror assemblies 40 are also referred in drawings as Heliostats. The receiver assembly 1 has sufficient strength to support receiver units and resist all vertical and lateral loads. The support post (also referred to as a receiver array frame support post) 2 has sufficient strength to carry all components and resist all vertical and lateral loads. The support posts 2 are secured to a foundation sufficient in strength to carry all components and resist all vertical and lateral loads. In this example, the plurality of receiver units of the receiver assembly 1 are arranged along a north-south axis, as shown in FIG. 2.

The plurality of flat mirror assemblies 40 may be provided on the ground on one side or both sides of the tower 50, and may be arranged in rows. In accordance with one embodiment of the present invention, as shown in FIG. 1, the plurality of flat mirror assemblies 40 include an east array of the heliostats 3 and a west array of heliostats 4.

The east array of heliostats 3 are located on the east side of the receiver assembly 1 (the tower 50). Each row the east array is at a certain distance from the tower 50, and adjacent rows are at a specified spacing therebetween so as to effectively focus sunlight to the receiver array 1. The Heliostats rotate about one axis and focus light to the receiver array 1. Similarly, the west array of Heliostats 4 are located on the west side of the receiver assembly 1 (the tower 50). Each row of the west array 4 is at a certain distance from the tower 50, and adjacent rows are at a specified spacing therebetween so as to effectively focus sunlight to the receiver array 1. Each of the plurality of flat mirror assemblies 40 rotates about one axis and focus light to the receiver array 1. Each of the plurality of flat mirror assemblies 40 may direct the sunlight to at least two receiver units.

The receiver assembly 1 may be configured to track the sun (reflected from the flat mirror assemblies 40) in a first direction, and the plurality of flat mirror assemblies 40 may be configured to track the sun in a second direction. The first direction may be a north-south direction and the second direction may be an east-west direction. Each of the receiver units in the receiver assembly 1 may be configured to rotate around a first axis, using a first single-axis tracker (a first motor). The first axis may be perpendicular to the first direction. Each of the flat mirror assemblies 40 may be configured to rotate around a second axis, using a second single-axis tracker (a second motor). The second axis may be perpendicular to the second direction. Accordingly, a dual axis tracking is realized using two separate and independent single-axis trackers implemented in the receiver assembly 1 and the flat mirror assemblies 40. The first motor and the second motor may be independently controlled in a synchronized manner so as to provide a dual-axis control for tracking the sun. The second motor may rotate the plurality of flat mirror assemblies 40 row by row with respect to the receiver assembly 1.

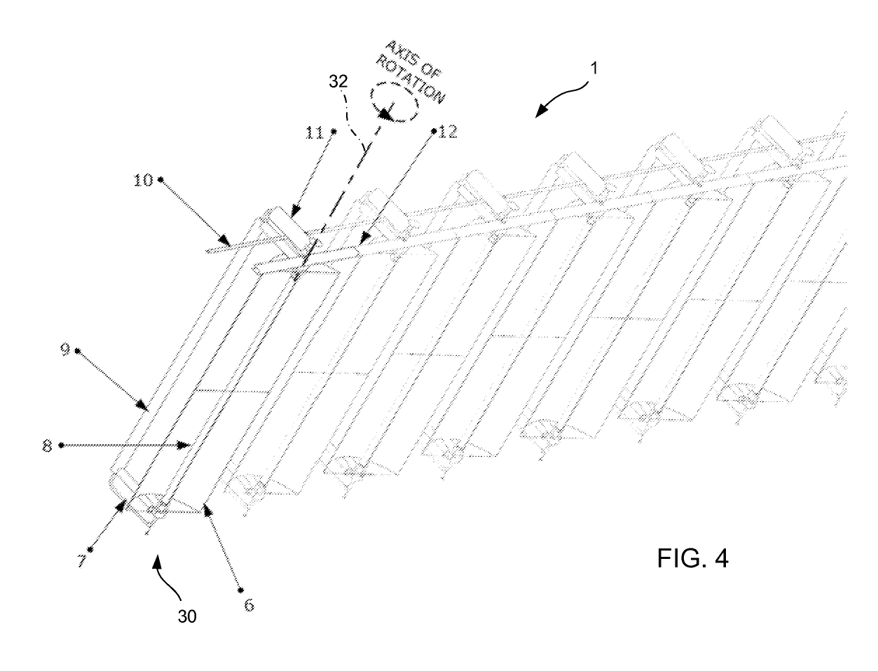

FIG. 3 is a schematic diagram illustrating an overall design of the large-scale integrated solar system 200 in accordance with another embodiment of the present invention. In this example, the plurality of receiver units in the receiver assembly are arranged along an east-west axis.

As shown in FIG. 3, the receiver assembly 1 receives focused light from the plurality of flat mirror assemblies 40 (also referred in drawings as Heliostats). The receiver assembly 1 has sufficient strength to support the plurality of receiver units and resist all vertical and lateral loads. The support post 2 (also referred to as a receiver array frame support post) has sufficient strength to carry all components and resist all vertical and lateral loads. The support posts 2 are secured to a foundation sufficient in strength to carry all components and resist all vertical and lateral loads.

In this example, the plurality of flat mirror assemblies 40 includes a south array of Heliostats 5 located on the south side of the receiver assembly 1 (the tower 50). Each row of the south array 5 is at a certain distance from the tower 50, and adjacent rows are at a specified spacing therebetween so as to effectively focus sunlight to the receiver array 1. The Heliostats rotate about one axis (a second axis) and focus light to the receiver array 1. The large-scale integrated solar system 200 may be controlled in a similar manner as that of large-scale integrated solar system 100 though the directions are different.

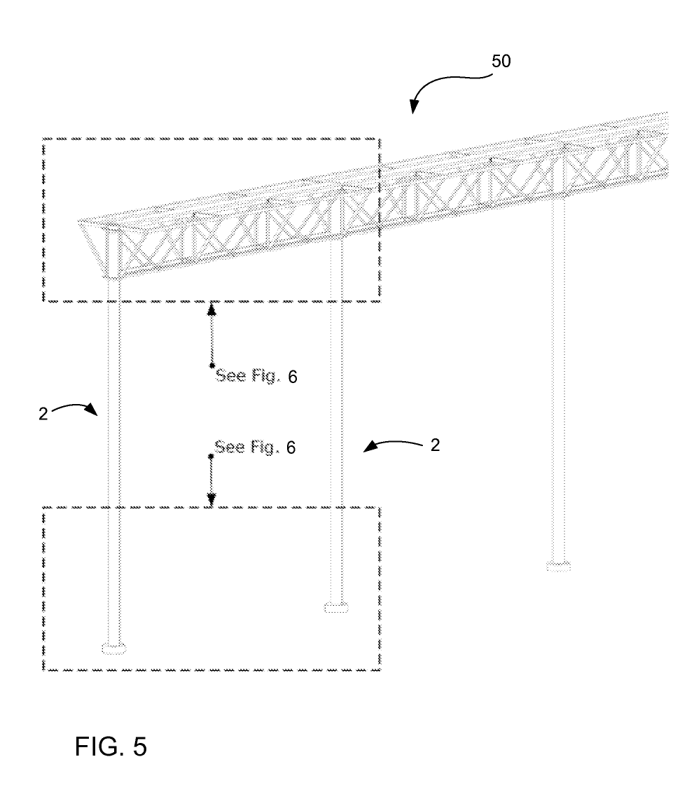

FIG. 4 illustrates a structure of the receiver assembly 1 in accordance with one embodiment of the present invention. Each receiver unit 30 includes a reflective focusing element, a coolant piping 7, a liquid-cooled receiver element 8 having photovoltaic converters. The reflective focusing element 6 may be of a construction such that it can reflect and focus light to the receiver element 8. The coolant piping 7 forms a closed loop which allows liquid to flow from receiver element 8 to a coolant tank 11 and back to the receiver element 8.

The receiver element 8 is constructed such that it can contain either a liquid or gas coolant which surrounds the photovoltaic converters (not shown). The receiver element 8 allows for coolant to flow in and out of itself. The receiver element 8 allows for electricity to flow in and out of itself. The receiver element 8 is attached to the reflective focusing element 6 at a distance from surface to the reflective focusing element 6 which allows light to be focused from reflective focusing element 6 to the receiver element 8.

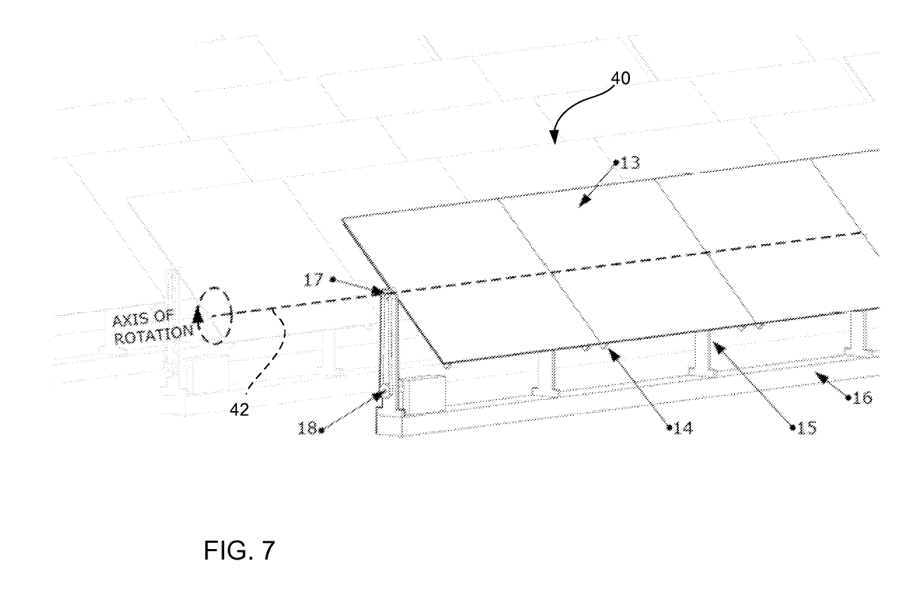

The receiver frame 9 supports the reflective focusing element 6, a tracking linkage 10, the coolant tank 11, the coolant piping 7, and the receiver element 8. The receiver frame 9 is attached to a top rail 24 and a bottom rail 23 of a receiver support truss frame 20 (see FIG. 6). The receiver frame 9 has sufficient strength to carry all components and resist all vertical and lateral loads.

A one-axis tracking linkage 10 connects the reflective focusing element 6 and the receiver element 8 of each individual receiver unit 30 together in an array. The one-axis tracking linkage 10 controls and manipulates the angle of each receiver unit 30 together as an array around an axis of rotation (a first axis) 32. The first axis 32 may be perpendicular to the direction in which the plurality of receiver units are arranged to form the receiver array. The coolant tank 11 connects to the coolant piping 7. A tracking guard 12 protects the tracking mechanism from weather and exposure of sunlight.

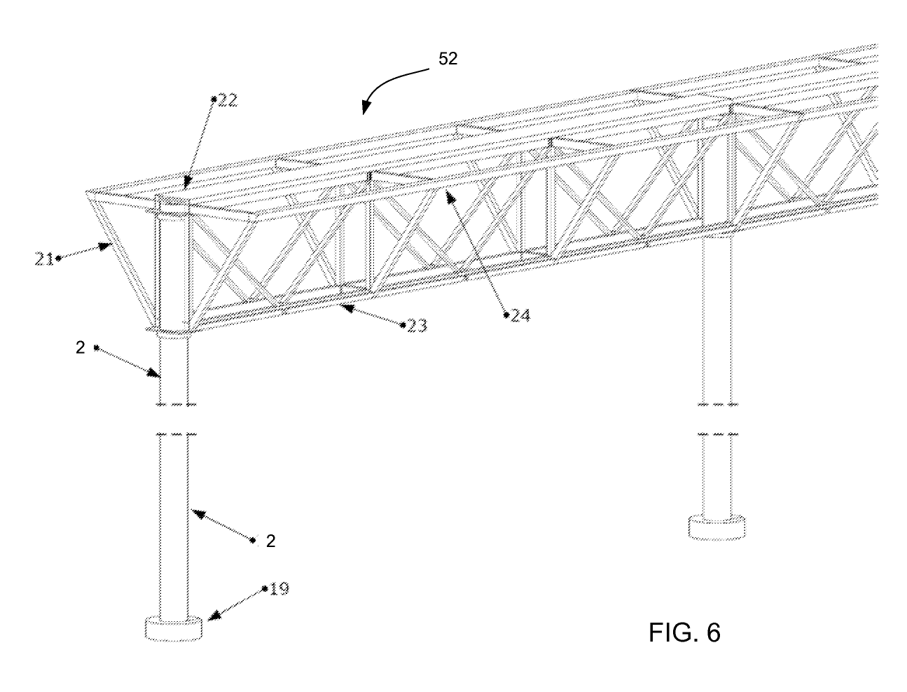

FIG. 5 illustrates a structure of the tower 50 having a receiver support truss assembly 52 and a plurality of support posts 2 in accordance with one embodiment of the present invention. FIG. 6 illustrates more details of the receiver support truss assembly 52 and the support post 2. As shown in FIG. 6, the receiver support truss assembly 52 includes a receiver support truss 21, a power cable chase 22, a receiver mount having a bottom rail 23 and a top rail 24.

A frame support base (post base) 19 is connected to the support post 2, and provides a foundation sufficient in strength to carry all components and resist all vertical and lateral loads. The support post 2 is connected to the post base 19 and to the receiver support truss assembly 52, and is sufficient in strength to carry all components and resist all vertical and lateral loads.

The receiver support truss 21 is constructed as a triangulated truss, and supports and secures the plurality of receiver units. The receiver support truss 21 is connected to at least two support posts 2. The frame support base (post base) 19 is sufficient in strength to carry all components and resist all vertical and lateral loads. The power cable chase 22 provides a platform to carry the electrical and or coolant lines. The power cable chase 22 may be located on top of the receiver support truss 21.

The bottom rail 23 of the receiver mount provides for secure mounting of each of the individual receiver units. The bottom rail 23 of the receiver mount is secured to the receiver support truss 21 and is sufficient in strength to carry all components and resist all vertical and lateral loads. Similarly, the top rail 24 of the receiver mount provides for secure mounting of each of the individual receiver units. The top rail 24 of the receiver mount is secured to the receiver support truss 21 and is sufficient in strength to carry all components and resist all vertical and lateral loads.

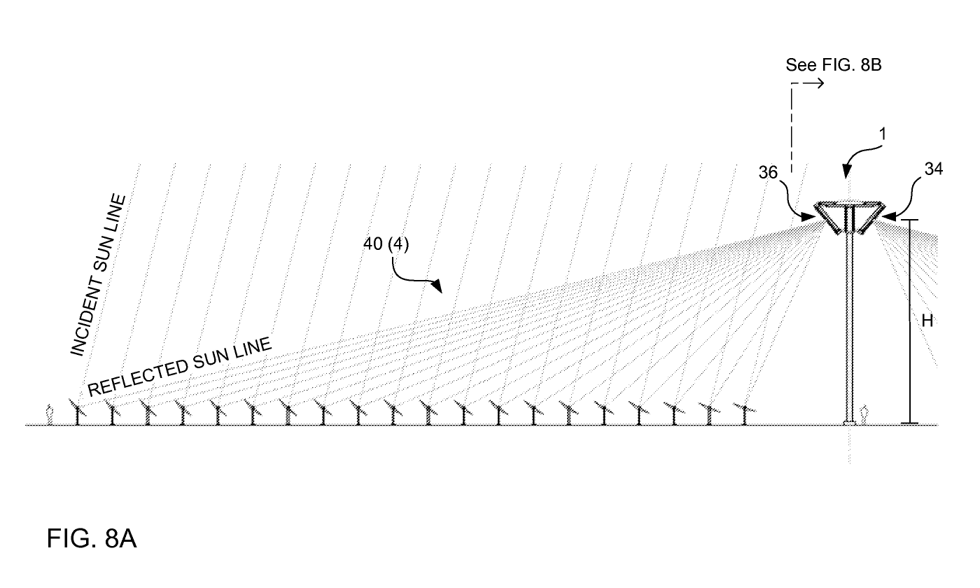

FIG. 7 illustrates a structure of a flat mirror assembly (Heliostat) 40 in accordance with one embodiment of the present invention. The flat mirror assembly 40 includes a focusing element 13 which can reflect and focus light from the sun to the receiver assembly 1. The focusing element 13 may rotate about one axis (an axis of rotation, the second axis) 42. A row of minors may be attached together and manipulated as a plurality of flat mirrors to focus light to the receiver assembly 1. The flat mirror assembly 40 also includes a heliostat frame 14 which supports the focusing element 13. The heliostat frame 14 is connected to a rotation shaft 17. The heliostat frame 14 is sufficient in strength to carry all components and resist all vertical and lateral loads.

The flat mirror assembly 40 may also include frame support legs 15 which are coupled to the rotation shaft 17 and support the heliostat frame 14 and focusing element 13. The frame support legs 15 are anchored to a foundation of sufficient strength to carry all components and resist all vertical and lateral loads. A frame support base 16 is sufficient in strength to carry all components and resist all vertical and lateral loads.

The one-axis heliostat rotation shaft 17 is connected to a one-axis tracker motor and control 18 which control rotation of the focusing element 13 such that light can be focused to the receiver assembly 1. The one-axis tracker motor and control 18 is a motorized system which can control the plurality of flat mirrors and focus light from the heliostats the receivers.

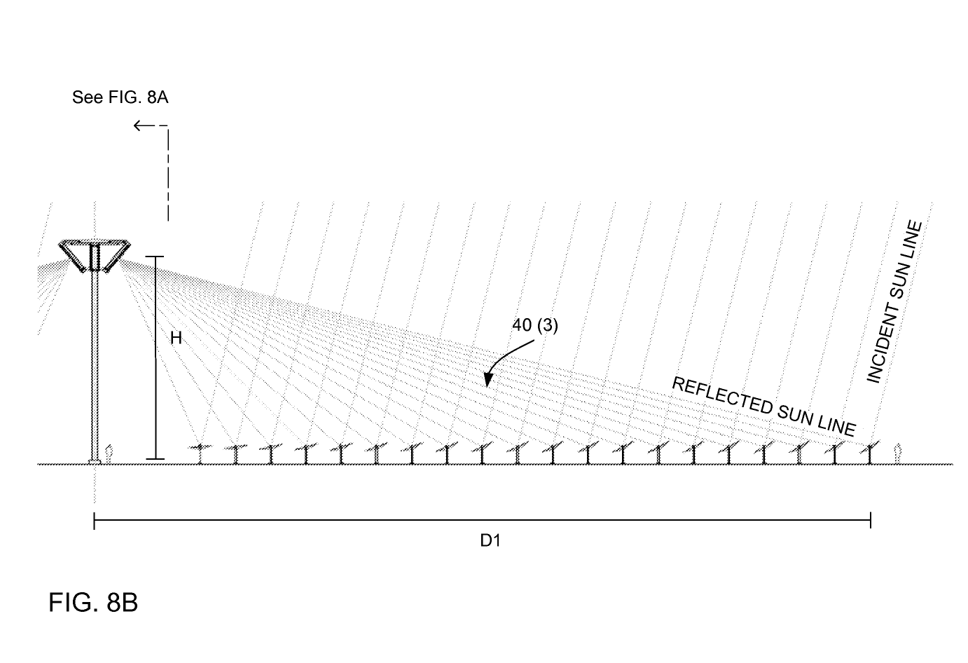

FIGS. 8A and 8B schematically illustrate an example of a large-scale integrated system in accordance with one embodiment of the present invention. As shown in FIGS. 8A and 8B, the receiver assembly 1 includes a first array of receiver units 34 provided on one side, for example, the east side, of the tower 50, and a second array of receive units 36 provided on the other side, for example, the west side, of the tower 50. The first array of receiver units 34 and the second array of receiver units 36 are both arranged in the same direction, for example, the north-south direction. The rotation axis for each of the receiver units 34 in the first array may be tilted by a first angle with respect to a vertical direction. The first axis for each of the receiver units 36 in the second array may be tilted by a second angle with respect to the vertical direction.

The first angle may be determined based on a height (H) of the tower 50 and a distance (D1) between the tower 50 and a farthest one of the plurality of flat mirror assemblies 40 (the east array 3) provided on the first side of the tower, as shown in FIG. 8B. The second angle may be determined based on the height (H) of the tower 50 and a distance (D2) between the tower 50 and a farthest one of the plurality of flat mirror assemblies 40 (the west array 4) provided on the second side of the tower.

While the embodiments of the invention presented here are intended for use as collectors of solar energy, other applications of the current invention are envisioned. For example, the invention could be used to concentrate radiant energy from other astronomical bodies such as stars, planets, or satellites. This would be useful in the fields of astronomy and communications.

In accordance with one embodiment of the present invention, the receiver assembly may be configured to track an astronomical body such as a star or planet in a first direction, and the plurality of flat mirror assemblies are configured to track said astronomical body in a second direction. In accordance with anther embodiment of the present invention, the receiver assembly may be configured to track the position of an artificial satellite in a first direction, and the plurality of flat mirror assemblies are configured to track the satellite in a second direction for the purpose of receiving electromagnetic signals from said satellite.

While this invention has been described in terms of several preferred embodiments, there are alterations, permutations, modifications, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A large-scale integrated radiant energy collector, comprising:
a receiver assembly including a plurality of receiver units, each receiver unit including:
a radiant energy absorber; and
a focusing optic configured to concentrate received light onto the radiant energy absorber;
a plurality of flat mirror assemblies configured to receive radiant energy and direct the radiant energy toward the receiver assembly; and
a tower configured to support the receiver assembly above the plurality of flat mirror assemblies.

2. The large-scale integrated radiant energy collector of claim 1, wherein the plurality of flat mirror assemblies are provided on the ground on one or both sides of the tower and arranged in rows.

3. The large-scale integrated radiant energy collector of claim 1, wherein the receiver assembly is configured to track the sun in a first direction, and the plurality of flat mirror assemblies are configured to track the sun in a second direction.

4. The large-scale integrated radiant energy collector of claim 3, wherein each of the receiver units is configured to rotate around a first axis perpendicular to the first direction, and each of the flat mirror assemblies is configured to rotate around a second axis perpendicular to the second direction.

5. The large-scale integrated radiant energy collector of claim 4, wherein the receiver assembly includes:
a first array of receiver units provided on a first side of the tower and arranged in the first direction; and
a second array of receive units provided on a second side of the tower opposite to the first side and arranged in the first direction,
wherein the first axis for each of the receiver units in the first array is tilted by a first angle with respect to a vertical direction,
and wherein the first axis for each of the receiver units in the second array is tilted by a second angle with respect to the vertical direction.

6. The large-scale integrated radiant energy collector of claim 5, wherein the first angle is determined based on a height of the tower and a distance between the tower and a farthest one of the plurality of flat mirror assemblies provided on the first side of the tower,
and wherein the second angle is determined based on the height of the tower and a distance between the tower and a farthest one of the plurality of flat mirror assemblies provided on the second side of the tower.

7. The large-scale integrated radiant energy collector of claim 4, further comprising:
a first motor for rotating each of the receiver units around the first axis; and
a second motor for rotating each of the flat mirror assemblies around the second axis.

8. The large-scale integrated radiant energy collector of claim 3, further comprising:
a first motor configured to rotate each of the receiver units around a first axis perpendicular to the first direction; and
a second motor configured to rotate each of the flat mirror assemblies around a second axis perpendicular to the second direction.

9. The large-scale integrated radiant energy collector of claim 8, wherein the first motor and the second motor are independently controlled in a synchronized manner so as to provide a dual-axis control for tracking the sun.

10. The large-scale integrated radiant energy collector of claim 8, wherein the second motor rotates the plurality of flat mirror assemblies row by row with respect to the receiver assembly.

11. The large-scale integrated radiant energy collector of claim 1, wherein each of the plurality of flat mirror assemblies directs the sunlight to at least two receiver units.

12. The large-scale integrated radiant energy collector of claim 1, wherein the tower accommodates a cable for transmitting the electricity generated by the receiver assembly.

13. The large-scale integrated radiant energy collector of claim 1, wherein the tower includes a receiver mount portion and at least one pole.

14. The large-scale integrated radiant energy collector of claim 1, wherein the first direction is a north-south direction and the second direction is an east-west direction.

15. The large-scale integrated radiant energy collector of claim 1, wherein the radiant energy absorber is a photovoltaic device for converting light energy into electrical energy.

16. The large-scale integrated radiant energy collector of claim 1, wherein the radiant energy absorber is a thermal absorber for converting light energy into heat.

17. The large-scale integrated radiant energy collector of claim 1, wherein the radiant energy absorber is a hybrid photovoltaic and thermal absorber for converting a portion of light energy into electricity, and a portion into heat.

18. The large-scale integrated radiant energy collector of claim 1, wherein the focusing optic in the receiver is a reflector configured to focus light on the radiant energy absorber.

19. The large-scale integrated radiant energy collector of claim 17, wherein the reflector is a parabolic mirror.

20. The large-scale integrated radiant energy collector of claim 1, wherein the focusing optic in the receiver is a refractive lens.

21. The large-scale integrated radiant energy collector of claim 1, wherein the focusing optic in the receiver is a linear Fresnel lens.

22. The large-scale integrated radiant energy collector of claim 1, wherein the focusing optic in the receiver is a Fresnel lens.

23. The large-scale integrated radiant energy collector of claim 1, wherein the receiver assembly is configured to track an astronomical body such as a star or planet in a first direction, and the plurality of flat mirror assemblies are configured to track said astronomical body in a second direction.

24. The large-scale integrated radiant energy collector of claim 1, wherein the receiver assembly is configured to track the position of an artificial satellite in a first direction, and the plurality of flat mirror assemblies are configured to track the satellite in a second direction for the purpose of receiving electromagnetic signals from said satellite.
